(19) United States
(12) Patent Application Publication
(10) Pub. No.: US 2023/0287165 A1
(43) Pub. Date: Sep. 14, 2023

(54) VERTICALLY PHASE-SEPARATED BLOCK COPOLYMER LAYER

(71) Applicant: NISSAN CHEMICAL CORPORATION, Tokyo (JP)

(72) Inventors: Ryuta MIZUOCHI, Toyama-shi (JP); Hiroyuki WAKAYAMA, Toyama-shi (JP); Mamoru TAMURA, Toyama-shi (JP); Makoto NAKAJIMA, Toyama-shi (JP); Rikimaru SAKAMOTO, Toyama-shi (JP)

(73) Assignee: NISSAN CHEMICAL CORPORATION, Tokyo (JP)

(21) Appl. No.: 18/015,417

(22) PCT Filed: Aug. 18, 2021
(86) PCT No.: PCT/JP2021/030150

§ 371 Date: Jan. 10, 2023

(30) Foreign Application Priority Data
Aug. 19, 2020 (JP) 2020-138906

(51) Int. Cl. C08F 293/00; C08G 77/00

(52) U.S. Cl. CPC C08F 293/00; C08G 77/80

(57) ABSTRACT

A layer contains a block copolymer in which a microphase-separated structure of the block copolymer has been induced to be perpendicular to a substrate, the process being difficult to perform by means of heating at atmospheric pressure. A method produces this layer. A method produces a semiconductor device in which a vertically phase-separated block copolymer layer is used. The vertically phase-separated block copolymer layer is formed by heating under a pressure below atmospheric pressure and at a temperature at which induced self-assembly can occur. It is preferable that the vertical phase separation includes a lamellar portion. It is preferable that the lamellar portion includes PMMA. It is preferable that the heating temperature is 290° C. or higher. It is preferable to additionally have a layer, which neutralizes the surface energy of the block copolymer, beneath the block copolymer layer.

### TECHNICAL FIELD

The present invention relates to a vertically phase-separated block copolymer layer (such as diblock copolymer layer, triblock copolymer layer, and tetrablock copolymer layer), or preferably a layer containing a vertically phase-separated polystyrene-block (hereinafter referred to as “b” for short) —polymethyl methacrylate (PS-b-PMMA), formed by utilizing self-assembly technique of a block copolymer in the semiconductor lithography, a method for producing the aforementioned layer, and a method for manufacturing a semiconductor device using the vertically phase-separated block copolymer layer or preferably the vertically phase-separated PS-b-PMMA layer.

### BACKGROUND ART

In recent years, further miniaturization of a large-scale integrated circuit (LSI) has required technology for processing a finer structure. To meet the demand, a practical application of patterning technology for forming a finer pattern is anticipated: the patterning technology utilizes a phase separated structure formed by self-assembly of a block copolymer having incompatible polymers bonded to each other. For example, the following patterning technique has been proposed: a self-assembled film containing a block copolymer having two or more polymers bonded is formed on a surface of a substrate, and the block copolymer in the self-assembled film is phase-separated, followed by selectively removing the phase of at least one type of polymer included in the block copolymer, thereby forming a pattern. Patent Literature 1 discloses an underlayer film-forming composition for a self-assembled film containing a polycyclic aromatic vinyl compound. Non Patent Literature 1 discloses a technique, in which the oxygen concentration in an atmosphere is reduced to cause directed self-assembly of a self-assembled film.

### CITATION LIST

### Patent Literature

Patent Literature 1: WO 2014/097993 A

### Non Patent Literature

Non Patent Literature 1: Nathalie Frolet et al., “Expanding DSA process window with atmospheric control”, Proc. of SPIE Vol. 11326 113261J-1 to J-6(2020)

### SUMMARY OF INVENTION

### Technical Problem

An object of the invention is to provide a layer comprising a block copolymer, or preferably PS-b-PMMA, in which a microphase-separated structure of the block copolymer, or preferably PS-b-PMMA, is vertically directed relative to a substrate without causing disorder, which is difficult to achieve by heating under atmospheric pressure; and to provide a method for producing the same and a method for manufacturing a semiconductor device using a vertically phase-separated block copolymer (preferably PS-b-PMMA) layer.

### Solution to Problem

The invention embraces the following.

[1] A layer comprising a block copolymer having a vertically phase-separated structure, the layer being formed by heating at a temperature at which a directed self-assembly may occur under a pressure below atmospheric pressure.

[2] The layer comprising a block copolymer having a vertically phase-separated structure according to [1], wherein the block copolymer is PS-b-PMMA.

[3] The layer comprising a block copolymer having a vertically phase-separated structure according to [1] or [2], wherein the vertically phase-separated structure includes a lamellar portion.

[4] The layer comprising a block copolymer having a vertically phase-separated structure according to any one of [1] to [3], wherein the heating is carried out at a temperature of 290° C. or higher.

[5] The layer comprising a block copolymer having a vertically phase-separated structure according to any one of [1] to [4], which further comprises under a layer of the block copolymer a neutralization layer that neutralizes a surface energy of the block copolymer.

[6] The layer comprising a block copolymer having a vertically phase-separated structure according to [5], wherein the neutralization layer comprises a polymer having an aromatic compound-derived unit structure.

[7] The layer comprising a block copolymer having a vertically phase-separated structure according to [6], wherein the aromatic compound-derived unit structure accounts for 50% by mole or more of the polymer.

[8] The layer comprising a block copolymer having a vertically phase-separated structure according to [5], wherein the neutralization layer comprises a polymer having in its main chain a unit structure including an aliphatic polycyclic structure of an aliphatic polycyclic compound.

[9] The layer comprising a block copolymer having a vertically phase-separated structure according to [5], wherein the neutralization layer comprises a polysiloxane.

[10] The layer comprising a block copolymer having a vertically phase-separated structure according to any one of [5] to [7], wherein the neutralization layer comprises a polymer having a reactive substituent at a terminal.

[11] The layer comprising a block copolymer having a vertically phase-separated structure according to any one of [1] to [9], which is formed on a substrate.

[12] A method for producing a layer comprising a block copolymer having a vertically phase-separated structure, the method comprising:
forming a layer comprising a block copolymer on a substrate; and
heating the substrate under a pressure below atmospheric pressure.

[13] A method for manufacturing a semiconductor device, the method involving:
forming a layer comprising a block copolymer on a substrate;
heating the substrate under a pressure below atmospheric pressure;
etching the layer containing the block copolymer having a vertically phase-separated structure; and
etching the substrate.

### Advantageous Effects of Invention

A vertically phase-separated block copolymer layer, or preferably a PS-b-PMMA layer, herein is a vertically phase-separated block copolymer layer, preferably a vertically phase-separated block copolymer PS-b-PMMA layer (which may be a layer containing PS-b-PMMA, but preferably a layer consisting of PS-b-PMMA), preferably a block copolymer layer having at least a lamellar shape (which may have any shape as long as it includes one or more lamellar shapes), preferably a PS-b-PMMA layer having at least a lamellar shape, preferably a block copolymer layer having a lamellar shape, or preferably a PS-b-PMMA layer having a lamellar shape each of which is formed by heating the block copolymer layer, or preferably the PS-b-PMMA layer, before the phase separation under a pressure below atmospheric pressure to cause directed self-assembly of the block copolymer, or preferably the PS-b-PMMA, to direct a microphase-separated structure vertically on a substrate. Selectively etching the vertically phase-separated block copolymer layer, or preferably the PS-b-PMMA-containing layer, enables treatment of a semiconductor substrate and manufacture of a semiconductor device.

### BRIEF DESCRIPTION OF DRAWINGS

FIG. 1 is a schematic view of directed self-assembly of PS-b-PMMA.

FIG. 2 is a schematic view of a substrate, an underlayer film layer (referred to as “neutralization layer” herein), and a self-assembled layer (referred to as “PS-b-PMMA layer” herein).

FIG. 3 is an electron micrograph illustrating “vertical order” and “disorder” referred to herein.

### DESCRIPTION OF EMBODIMENTS

<Vertically Phase-Separated Block Copolymer Layer>

Herein, a block copolymer layer, or preferably a PS-b-PMMA layer, having a vertically phase-separated structure is produced by applying a known block copolymer layer, preferably a PS-b-PMMA-containing block copolymer layer-forming composition, or preferably a PS-b-PMMA layer-forming composition, to a substrate and by heating the substrate under a pressure below atmospheric pressure.

The vertically phase-separated structure may occur in at least a part of the block copolymer layer, or preferably a part of the PS-b-PMMA layer. However, the vertical phase separation preferably occurs throughout the block copolymer layer, or preferably throughout the PS-b-PMMA layer (that is, vertically phase-separated areas preferably account for 80% or more, more preferably 90% or more, still more preferably 95% or more, and still more preferably 100% of the total surface to which the block copolymer layer, or preferably the PS-b-PMMA layer, is applied). After the phase separation, at least three spots in a part of the upper surface of the substrate are examined by an electron microscope, and the vertically phase-separated areas are determined from the average of vertically phase-separated areas in electron microscope images examined. In examination of the electron microscope images captured from above the part of the substrate surface after the phase separation, those including a disordered area, as shown in electron micrographs of FIG. 3, are determined as having “disorder.”

PS-b-PMMA, or a diblock copolymer, is produced by a known method. Commercially available block copolymers are also applicable.

Also, the block copolymer may be a block copolymer obtained by making a linkage between a silicon-containing polymer having styrene substituted with a silicon-containing group as a constituting unit, and a silicon-free polymer having, as a constituting unit, either styrene optionally substituted with an organic group or a derivative of such styrene or a silicon-free polymer having a lactide-derived structure as a constituting unit.

Particularly, preferred is a combination of a silylated polystyrene derivative and a polystyrene derivative polymer or a combination of a silylated polystyrene derivative polymer and polylactide.

More particularly, preferred is a combination of a silylated polystyrene derivative having a substituent in 4-position and a polystyrene derivative polymer having a substituent in 4-position or a combination of a silylated polystyrene derivative polymer having a substituent in 4-position and polylactide.

More preferably, specific examples of the block copolymer include a combination of poly(trimethylsilylstyrene) and polymethoxystyrene, a combination of polystyrene and poly(trimethylsilylstyrene), and a combination of poly(trimethylsilylstyrene) and poly(D, L-lactide)

Still more preferably, specific examples of the block copolymer include a combination of poly(4-trimethylsilylstyrene) and poly(4-methoxystyrene), a combination of polystyrene and poly(4-trimethylsilylstyrene), and a combination of poly(4-trimethylsilylstyrene) and poly(D, L-lactide).

The two most preferable examples of the block copolymer are poly(4-methoxystyrene)/poly(4-trimethylsilylstyrene) copolymer and polystyrene/poly(4-trimethylsilylstyrene) copolymer.

The entire disclosure in WO 2018/135456 A is incorporated herein by reference.

Also, the block copolymer may be a block copolymer obtained by making a linkage between a silicon-free polymer and a silicon-containing polymer having styrene substituted with a silicon-containing group as a constituting unit; and the silicon-free polymer may be a block copolymer having a unit structure represented by the following Formula (1-1c) or Formula (1-2c).

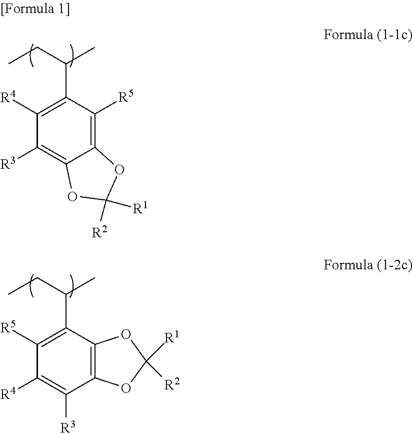

(In Formula (1-1c) or Formula (1-2c), R¹ and R² independently are a hydrogen atom, a halogen atom, or a C₁-C₁₀ alkyl group, and R³ to R⁵ independently are a hydrogen atom, a hydroxy group, a halogen atom, a C₁-C₁₀ alkyl group, a C₁-C₁₀ alkoxy group, a cyano group, an amino group, an amide group, or a carbonyl group.)

The silicon-containing group may contain one silicon atom.

The silicon-containing polymer may have a unit structure represented by the following Formula (2c).

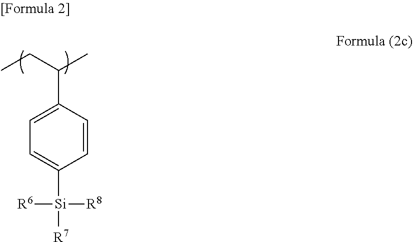

(In Formula (2c), R⁶ to R⁸ independently are a C₁-C₁₀ alkyl group or a C₆-C₄₀ aryl group.)

Moreover, the block copolymer may employ the block copolymers disclosed in JP 2019-507815 W, including the following [BCP1] to [BCP4].
[BCP1] A block copolymer containing 5-vinylbenzo[d][1,3]dioxole.
[BCP2] Block copolymer [BCP1] further including a silicon-containing block.
[BCP3] Block copolymer [BCP2] further containing pentamethyl disilylstyrene.
[BCP4] Block copolymer [BCP3] being poly(5-vinylbenzo[d][1,3]dioxole)-b-poly(pentamethyl disilylstyrene).

The following scheme 1 shows the synthesis of the aforementioned poly(5-vinylbenzo[d][1,3]dioxole-block-4-pentamethyl disilylstyrene).

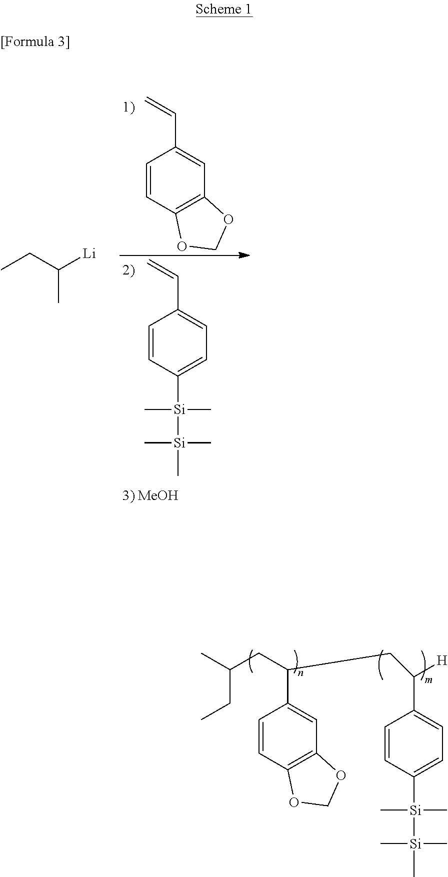

Preferably, the silicon-containing polymer or the silicon-containing block is poly(4-trimethylsilylstyrene) derived from 4-trimethylsilylstyrene. Preferably, the silicon-containing polymer or the silicon-containing block is poly(pentamethyl disilylstyrene) derived from pentamethyl disilylstyrene. The C₆-C₄₀ aryl group represents a monovalent group of a monocyclic or polycyclic aromatic hydrocarbon having 6 to 40 carbon atoms, and specific examples thereof include a phenyl group, a naphthyl group, or an anthryl group. The entire disclosure in WO 2020/017494 A is incorporated herein by reference.

Furthermore, a block copolymer from a combination of any of the following monomers is also applicable: styrene, methyl methacrylate, dimethylsiloxane, propylene oxide, ethylene oxide, vinylpyridine, vinylnaphthalene, D,L-lactide, methoxystyrene, methylenedioxystyrene, trimethylsilylstyrene, and pentamethyl disilylstyrene.

A useful block copolymer contains at least two blocks, and may be a block copolymer which contains separate blocks, of diblock, triblock, tetrablock, and so on, and each of the blocks may be homopolymer, random copolymer, or alternating copolymer.

Typical examples of the block copolymer include polystyrene-b-polyvinylpyridine, polystyrene-b-polybutadiene, polystyrene-b-polyisoprene, polystyrene-b-polymethyl methacrylate, polystyrene-b-polyalkenyl aromatic compound, polyisoprene-b-polyethylene oxide, polystyrene-b-poly(ethylene-propylene), polyethylene oxide-b-polycaprolactone, polybutadiene-b-polyethylene oxide, polystyrene-b-poly((meth)acrylate t-butyl), polymethyl methacrylate-b-poly(methacrylate t-butyl), polyethylene oxide-b-polypropylene oxide, polystyrene-b-polytetrahydrofuran, polystyrene-b-polyisoprene-b-polyethylene oxide, poly(styrene-b-dimethylsiloxane), polymethyl methacrylate-b-dimethylsiloxane), poly((meth)methyl acrylate-r-styrene)-b-polymethyl methacrylate, poly((meth)methyl acrylate-r-styrene)-b-polystyrene, poly(p-hydroxystyrene-r-styrene)-b-polymethyl methacrylate, poly(p-hydroxystyrene-r-styrene)-b-polyethylene oxide, polyisoprene-b-polystyrene-b-polyferrocenylsilane, and a block copolymer including at least one of these examples.

Also, the block copolymer may be a block copolymer containing the following organic polymer and/or metal-containing polymer in combination.

Typical examples of the organic polymer include, but are not limited to, poly(9,9-bis(6′-N,N,N-trimethylammonium)-hexyl)-fluorenphenylene) (PEP), poly(4-vinylpyridine) (4PVP), hydroxypropylmethylcellulose (HPMC), polyethylene glycol (PEG), poly(ethylene oxide)-poly(propylene oxide) diblock or multiblock copolymer, polyvinyl alcohol (PVA), poly(ethylene-vinyl alcohol) (PEVA), polyacrylic acid (PAA), polylactic acid (PLA), poly(ethyloxazoline), poly(alkyl acrylate), polyacrylamide, poly(N-alkyl acrylamide), poly(N,N-dialkyl acrylamide), polypropylene glycol (PPG), polypropylene oxide (PPO), partially or fully hydrogenated poly(vinyl alcohol), dextran, polystyrene (PS), polyethylene (PE), polypropylene (PP), polyisoprene (PI), polychloroprene (CR), polyvinyl ether (PVE), polyvinyl acetate (PVA), polyvinyl chloride (PVC), polyurethane (PU), polyacrylate, polymethacrylate, oligosaccharides, and polysaccharides.

Examples of the metal-containing polymer include, but are not limited to, a silicon-containing polymer such as polydimethylsiloxane (PDMS), polyhedral oligometric silsesquioxane (POSS), and poly(trimethylsilystyrene) (PTMSS) and a polymer containing silicon and iron such as poly(ferrocenyldimethylsilane) (PFS).

Typical examples of the block copolymer include, but are not limited to, diblock copolymers such as polystyrene-b-polydimethylsiloxane(PS-PDMS), poly(2-vinylpropylene)-b-polydimethylsiloxane (P2VP-PDMS), polystyrene-b-poly(ferrocenyldimethylsilane) (PS-PFS), and polystyrene-b-poly-DL-lactic acid (PS-PLA) or triblock copolymers such as polystyrene-b-poly(ferrocenyldimethylsilane)-b-poly(2-vinylpyridine) (PS-PFS-P2VP), polyisoprene-b-polystyrene-b-poly(ferrocenyldimethylsilane) (PI-PS-PFS), and polystyrene-b-poly(ferrocenyldimethylsilane)-b-polystyrene (PS-PTMSS-PS). In Example 1, a PS-PTMSS-PS block copolymer includes a poly(trimethylsilystyrene) polymer block including two chains of PTMSS connected by four styrene unit-containing linkers. Modifications of a block copolymer as disclosed in, for example, US 2012/0046415 A1 are also applicable.

Other examples of the block copolymer include a block copolymer obtained by making a linkage between a polymer having a (meth)acrylic acid ester as a constituting unit and a polymer having styrene or a derivative thereof as a constituting unit; a block copolymer obtained by making a linkage between a polymer having siloxane or a derivative thereof as a constituting unit and a polymer having styrene or a derivative thereof as a constituting unit; and a block copolymer obtained by making a linkage between a polymer having an alkylene oxide as a constituting unit and a polymer having a (meth)acrylic acid ester as a constituting unit. Note that the “(meth)acrylic acid ester” represents one or both of an acrylic acid ester having a hydrogen atom bonded to α-carbon and a methacrylic acid ester having a methyl group bonded to α-carbon.

An example of the (meth)acrylic acid ester include a (meth)acrylic acid having a carbon atom to which a substituent such as alkyl group and hydroxyalkyl group is bonded. Examples of the alkyl group used as the substituent include C₁-C₁₀ straight, branched, or cyclic alkyl groups. Specific examples of the (meth)acrylic acid ester include methyl (meth)acrylate, ethyl (meth)acrylate, propyl (meth)acrylate, cyclohexyl (meth)acrylate, octyl (meth)acrylate, nonyl (meth)acrylate, hydroxyethyl (meth)acrylate, hydroxypropyl (meth)acrylate, benzyl (meth)acrylate, anthracene (meth)acrylate, glycidyl (meth)acrylate, 3,4-epoxycyclohexyl methane (meth)acrylate, and propyltrimethoxysilane (meth)acrylate.

Examples of the derivative of styrene include α-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

Examples of the derivative of siloxane include dimethylsiloxane, diethylsiloxane, diphenylsiloxane, and methylphenylsiloxane.

Examples of the alkylene oxide include ethylene oxide, propylene oxide, isopropylene oxide, and butylene oxide.

Examples of the block copolymer include styrene-polyethyl methacrylate block copolymer, styrene-(poly-t-butyl methacrylate) block copolymer, styrene-polymethacrylic acid block copolymer, styrene-polymethyl acrylate block copolymer, styrene-polyethyl acrylate block copolymer, styrene-(poly-t-butyl acrylate) block copolymer, and styrene-polyacrylic acid block copolymer.

As a method for synthesizing a block copolymer, for example, a block copolymer is obtained by living radical polymerization, living cationic polymerization, or living anionic polymerization. Steps in these methods involve initiation and propagation but not a side reaction for deactivating a propagating site. Propagating sites can continue an active reaction for propagation during a polymerization reaction. Inhibiting the occurrence of chain transfer enables a polymer (A) having a uniform length. A monomer (b) different from this polymer (A) is added to a propagating site of the polymer (A), thereby promoting polymerization by the monomer (b) to form a block copolymer (AB).

For example, in a case where two types of blocks A and B are used, the molar ratio of a polymer chain (A) to a polymer chain (B) is preferably within the range of 1:9 to 9:1, or preferably 3:7 to 7:3.

The volume ratio in the block copolymer used in this disclosure is, for example, within the range of 30:70 to 70:30. A homopolymer A or B is a polymerizable compound having at least one radically polymerizable reactive group (vinyl group or vinyl group-containing organic group).

The block copolymer used in this disclosure preferably has a weight average molecular weight of within the range of 1,000 to 100,000 or 5,000 to 100,000 Mw. A weight average molecular weight below 1,000 Mw may degrade the coating properties to a base substrate, and a weight average molecular weight of 100,000 Mw or more may degrade the solubility in a solvent.

The polydispersity (Mw/Mn) of the block copolymer herein is preferably within the range of 1.00 to 1.50, and particularly preferably 1.00 to 1.20.

In an embodiment of the invention, the block copolymer is PS-b-PMMA.

A block copolymer layer-forming composition (preferably a PS-b-PMMA layer-forming composition) herein has a solid content of within the range of 0.1 to 10% by mass, 0.1 to 5% by mass, or 0.1 to 3% by mass. The solid content of the block copolymer layer-forming composition (preferably the PS-b-PMMA layer-forming composition) is a proportion after excluding a solvent.

The proportion of the block copolymer in the solid content may range from 30 to 100% by mass, from 50 to 100% by mass, from 50 to 90% by mass, or from 50 to 80% by mass.

<Solvent>

A solvent contained in the block copolymer layer-forming composition, or preferably the PS-b-PMMA layer-forming composition, herein is not particularly limited as long as it is capable of dissolving the block copolymer, or preferably PS-b-PMMA, but is preferably an organic solvent employed in the process of semiconductor lithography. Specific examples of the organic solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. These solvents may be used each alone or in combination of two or more thereof.

Of these solvents, preferable examples are propylene glycol monomethyl ether, propylene glycol monomethyl ether acetate, ethyl lactate, butyl lactate, butyl acetate, methyl isobutyl ketone, and cyclohexanone. Particularly, propylene glycol monomethyl ether and propylene glycol monomethyl ether acetate are preferable.

Alternatively, the solvent contained in the block copolymer layer-forming composition, or preferably the PS-b-PMMA layer-forming composition, may be a solvent disclosed in WO 2018/135456, that is, a combination of a low boiling point solvent (A) having a boiling point of 160° C. or lower and a high boiling point solvent (B) having a boiling point of 170° C. or higher.

The high boiling point solvent (B) may be contained in an amount of 0.3 to 2.0% by weight of the total solvent contained in the composition.

Preferred examples of the low boiling point solvent (A) having a boiling point of 160° C. or lower include propylene glycol monomethyl ether acetate (boiling point: 146° C.), n-butyl acetate (boiling point: 126° C.), and methyl isobutyl ketone (boiling point: 116° C.).

Preferred examples of the high boiling point solvent (B) having a boiling point of 170° C. or higher include N-methylpyrrolidone (boiling point: 204° C.), diethylene glycol monomethyl ether (boiling point: 193° C.), N,N-dimethylisobutylamide (boiling point: 175° C.), 3-methoxy-N,N-dimethylpropanamide (boiling point: 215° C.), and γ-butyrolactine (boiling point: 204° C.).

Two or more of each of the low boiling point solvent (A) and the high boiling point solvent (B) may be selected and mixed before use. As a preferred embodiment, the high boiling point solvent (B) is contained in an amount of 0.3 to 2.0% by weight of the total solvent contained in the composition. Most preferably, the high boiling point solvent (B) is contained in an amount of 0.5 to 1.5% by weight.

The atmospheric pressure refers to a pressure of 760,000 mTorr. A pressure below atmospheric pressure is not particularly limited as long as the pressure is below 760,000 mTorr and is preferably, for example, 500,000 mTorr or less, 300,000 mTorr or less, 100,000 mTorr or less, 50,000 mTorr or less, 30,000 mTorr or less, 20,000 mTorr or less, 10,000 mTorr or less, 9,000 mTorr or less, 8,000 mTorr or less, 7,000 mTorr or less, 6,000 mTorr or less, 5,000 mTorr or less, 4,000 mTorr or less, 3,000 mTorr or less, 2,000 mTorr or less, 1,000 mTorr or less, 900 mTorr or less, or 800 mTorr or less. For example, the pressure preferably ranges from 10,000 to 10 mTorr, 1,000 to 50 mTorr, or 800 to 50 mTorr.

A gas included in an atmosphere under a pressure below atmospheric pressure (an atmosphere during the directed self-assembly of the block copolymer, or preferably PS-b-PMMA) is not particularly limited. The atmosphere may be the air or may include N₂/O₂ mixed gas (in any mixing ratio), N₂ single gas, or O₂ single gas. The atmosphere may include other gases that have no impact on the directed self-assembly (vertical phase separation) of the block copolymer, or preferably PS-b-PMMA.

The heating represents a heating treatment to be described below in detail, which is performed on a film formed by applying a composition containing a block copolymer, or preferably PS-b-PMMA, on the upper surface of a typical flat plate semiconductor substrate (such as silicon wafer). The heating is carried out at a temperature at which the directed self-assembly occurs. The heating is typically carried out at a temperature ranging from 230° C. to 350° C. but preferably at a temperature of 290° C. or higher. In another embodiment, the heating is preferably carried out at a temperature ranging from 260° C. to 340° C., from 290° C. to 330° C., or from 290° C. to 320° C. The heating typically takes 1 minute to 1 hour but may take 2 minutes to 30 minutes, or 3 minutes to 10 minutes.

For example, at a temperature as high as 300° C. or more (a temperature ranging from 300° C. to 330° C.), the vertical phase separation can be achieved in a relatively short time such as 1 minute to 10 minutes, 1 minute to 5 minutes, or 1 minute to 3 minutes.

The vertically phase-separated structure preferably includes a lamellar portion. Herein, the term “lamellar” is used in the ordinary sense in the art. For example, a diblock copolymer AB (A and B each represent a block) has a structure in which blocks A and B are alternately self-organized (self-assembled) like “ . . . ABBAABBAAB . . . . ” A lamella has a structure with films stacked in parallel. In an embodiment, the lamella has what is called a fingerprint structure.

PS and PMMA in PS-b-PMMA each have a weight average molecular weight ranging from, for example, 10,000 to 100,000. It is preferable to use a block copolymer containing PS having a weight average molecular weight larger than that of PMMA. The ratio of weight average molecular weight between PS and PMMA (PS/PMMA) is, for example, within the range of 5.0 to 0.1, 3.0 to 0.5, 2.0 to 0.6, 1.5 to 0.7, 1.2 to 0.8, 1.1 to 0.9, or it is 1.0.

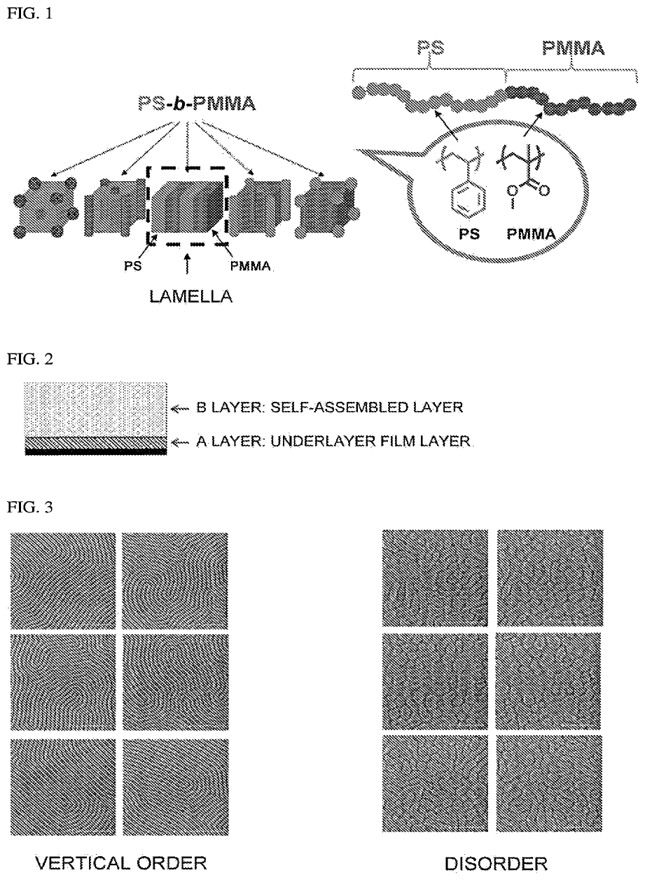

FIG. 1 shows a schematic view of a vertical phase-separated structure of a block copolymer layer in an example employing PS-b-PMMA as a block copolymer. A lamella having a structure enclosed by the dotted square in this example has PS portions and PMMA portions stacked in parallel to form a layer.

Under the block copolymer layer, or preferably the PS-b-PMMA layer, it is preferable to provide a neutralization layer for neutralizing surface energy of the block copolymer layer, or preferably PS-b-PMMA.

“Neutralizing surface energy” signifies to bring the surface energy of the total block copolymer having a hydrophilic portion (for example, PMMA) and a hydrophobic portion (for example, PS) close or equal to the surface energy of a surface of a substrate or the like in contact with the block copolymer in order to vertically phase-separate the block copolymer. When the block copolymer and the substrate have the same or similar surface energy, a vertical phase-separated structure is formed. For this reason, typically, for the vertical phase separation of the block copolymer layer, or preferably the PS-b-PMMA layer, the neutralization layer for neutralizing surface energy is formed on the substrate surface (that is, under the block copolymer layer, or preferably under the PS-b-PMMA layer) to neutralize surface energy except in a case where the substrate surface has the same or similar surface energy as the total block copolymer in advance. This theory is described in, for example, Macromolecules 2006, 39, 2449-2451.

The neutralization layer may contain a polymer having an aromatic compound-derived unit structure.

The aromatic compound preferably contains a C₆-C₄₀ aryl group.

Examples of the C₆-C₄₀ aryl group include phenyl group, o-methylphenyl group, m-methylphenyl group, p-methylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, and 9-phenanthryl group. Of these examples, the aromatic compound preferably contains a phenyl group, an α-naphthyl group (=1-naphthyl group), or a β-naphthyl group (=2-naphthyl group).

The aromatic compound preferably contains the α-naphthyl group (=1-naphthyl group) or β-naphthyl group (=2-naphthyl group) in an amount of 40% by mole or more, 45% by mole or more, 50% by mole or more, 60% by mole or more, 70% by mole or more, 80% by mole or more of the total polymer. The upper limit is, for example, 95% by mole or 90% by mole.

The polymer may be a polymer derived from, for example, 1-vinylnaphthalene, 2-vinylnaphthalene, or benzyl methacrylate. Preferably, the polymer may be a polymer derived from 2-vinylnaphthalene or benzyl methacrylate.

The polymer preferably contains the aromatic compound-derived unit structure in an amount of 50% by mole or more of the total polymer. More preferably, the polymer contains the aromatic compound-derived unit structure in an amount of, for example, 50% by mole to 99% by mole, 55% by mole to 99% by mole, 60% by mole to 99% by mole, 65% by mole to 99% by mole, 70% by mole to 99% by mole, 75% by mole to 99% by mole, 80% by mole to 99% by mole, 81% by mole to 99% by mole, 82% by mole to 98% by mole, 83% by mole to 97% by mole, 84% by mole to 96% by mole, or 85% by mole to 95% by mole of the total polymer.

The neutralization layer may be a neutralization layer derived from the underlayer film-forming composition for a self-assembled film disclosed in WO 2014/097993 A.

The neutralization layer may contain a polymer having a polycyclic aromatic vinyl compound-derived unit structure. The polymer may have the unit structure of the polycyclic aromatic vinyl compound in an amount of 0.2% by mole or more of the total unit structure of the polymer.

The polymer may have a unit structure of an aromatic vinyl compound in an amount of 20% by mole or more of the total unit structure of the polymer and may have the unit structure of the polycyclic aromatic vinyl compound in an amount of 1% by mole or more of the total unit structure of the aromatic vinyl compound.

The aromatic vinyl compound may contain an optionally substituted vinylnaphthalene, acenapthylene, or vinylcarbazole, and the polycyclic aromatic vinyl compound may be vinylnaphthalene, acenapthylene, or vinylcarbazole.

The aromatic vinyl compound may contain an optionally substituted styrene and an optionally substituted vinylnaphthalene, acenapthylene, or vinylcarbazole, and the polycyclic aromatic vinyl compound may be vinylnaphthalene, acenapthylene, or vinylcarbazole.

The aromatic vinyl compound may be an optionally substituted styrene and an optionally substituted vinylnaphthalene, acenapthylene, or vinylcarbazole, and the polycyclic aromatic vinyl compound may be an optionally substituted vinylnaphthalene, acenapthylene, or vinylcarbazole.

The aromatic vinyl compound may consist of a polycyclic aromatic vinyl compound, and the aromatic vinyl compound may be an optionally substituted vinylnaphthalene, acenapthylene, or vinylcarbazole.

The polymer may have the unit structure of the aromatic vinyl compound in an amount of 60 to 95% by mole of the total unit structure of the polymer.

The polymer may further have a unit structure containing a crosslink-forming group, and the crosslink-forming group may be a hydroxy group, an epoxy group, a protected hydroxy group, or a protected carboxy group.

The neutralization layer may be formed from a neutralization layer-forming composition. The neutralization layer-forming composition may contain the polymer having an aromatic compound-derived unit structure and/or the polymer having a polycyclic aromatic vinyl compound-derived unit structure, and the exemplary embodiments of these polymers are similar to those described in the neutralization layer. Herein, the term “underlayer film” may be used synonymously with the term “neutralization layer,” and the term “underlayer film-forming composition” may be used synonymously with the term “neutralization layer-forming composition.”

The neutralization layer-forming composition herein may include a crosslinking agent, an acid, or an acid generator.

<Crosslinking Agent>

Examples of the crosslinking agent used in the neutralization layer-forming composition herein include a melamine compound, a substituted urea-based compound, or polymer compounds of these compounds. The crosslinking agent is preferably a crosslinking agent having at least two crosslink-forming substituents and is specifically a compound such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or methoxymethylated thiourea. In addition, condensates of these compounds are applicable.

Furthermore, the crosslinking agent herein may be a nitrogen-containing compound disclosed in WO 2017/187969 A, which is bonded to a nitrogen atom and having two to six substituents represented by the following formula (1d) in one molecule.

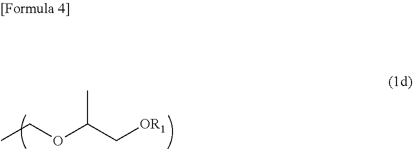

(In the formula, R₁ is a methyl group or an ethyl group.)

The nitrogen-containing compound having two to six substituents represented by formula (1d) in one molecule may be a glycoluril derivative represented by the following formula (1E).

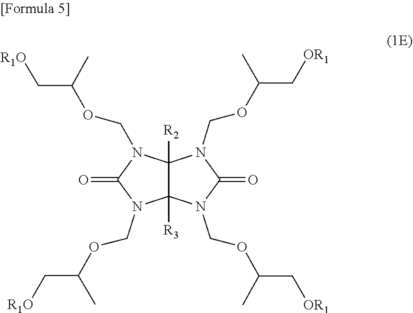

(In the formula, four R₁ independently are a methyl group or an ethyl group, and R₂ and R₃ independently are a hydrogen atom, a C₁-C₄ alkyl group, or a phenyl group.)

Examples of the glycoluril derivative represented by formula (1E) include compounds represented by the following formulae (1E-1) to (1E-6).

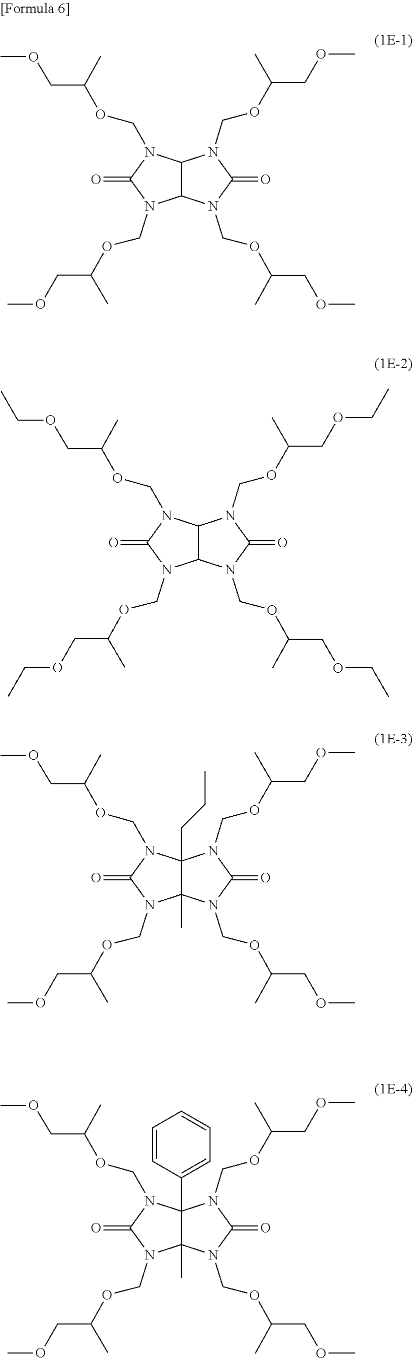

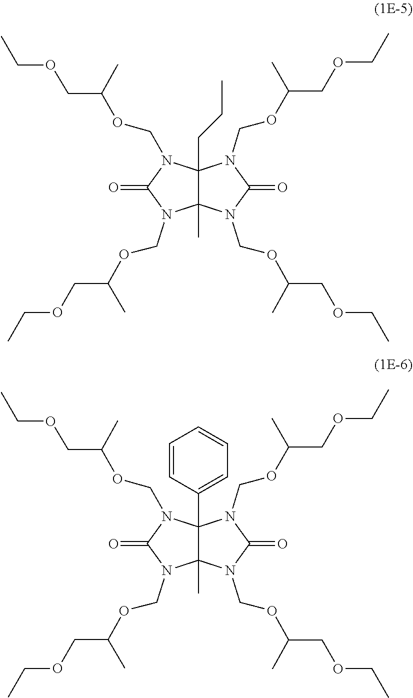

The nitrogen-containing compound having two to six substituents represented by formula (1d) in one molecule is obtained by reacting a nitrogen-containing compound bonded to a nitrogen atom and having two to six substituents represented by the following formula (2d) in one molecule and at least one compound represented by the following formula (3d).

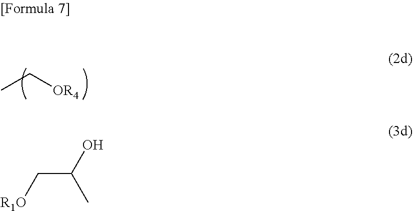

(In the formula, R₁ is a methyl group or an ethyl group, and R₄ is a C₁-C₄ alkyl group.)

The glycoluril derivative represented by formula (1E) is obtained by reacting the glycoluril derivative represented by the following formula (2E) and at least one compound represented by formula (3d).

The nitrogen-containing compound having two to six substituents represented by formula (2d) in one molecule may be, for example, a glycoluril derivative represented by the following formula (2E).

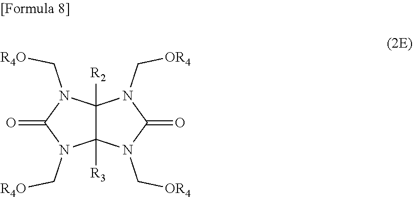

(In the formula, R₂ and R₃ independently are a hydrogen atom, a C₁-C₄ alkyl group, or a phenyl group, and each R₄ independently is a C₁-C₄ alkyl group.)

Examples of the glycoluril derivative represented by formula (2E) include compounds represented by the following formulae (2E-1) to (2E-4). Moreover, examples of the compound represented by formula (3d) include compounds represented by, for example, the following formulae (3d-1) and (3d-2).

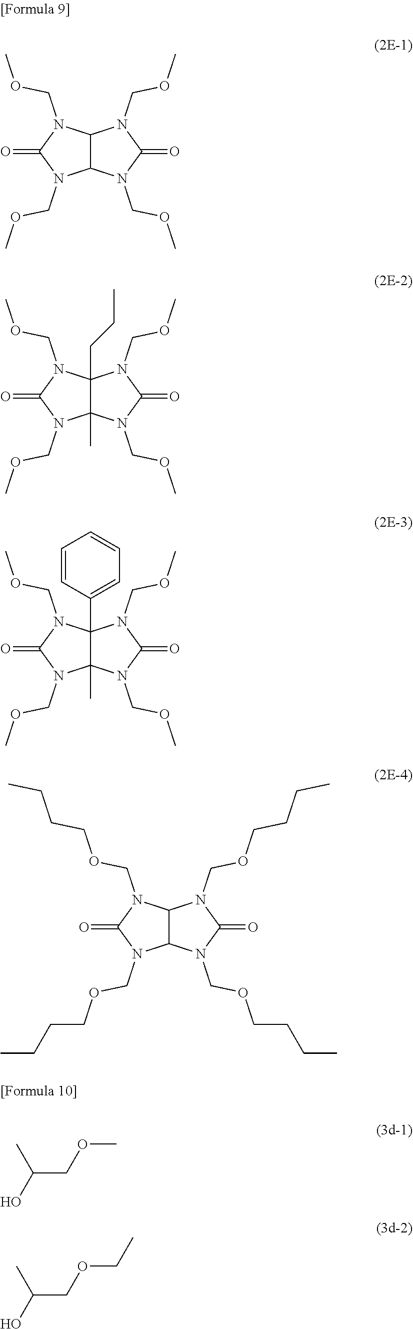

Details of the nitrogen-containing compound bonded to a nitrogen atom and having two to six substituents represented by the following formula (1d) in one molecule is based on the disclosure in WO 2017/187969 A.

The crosslinking agent is added to the neutralization layer-forming composition of the invention in an amount of 0.001 to 80% by mass, preferably 0.01 to 50% by mass, and more preferably 0.05 to 40% by mass of the total solid content. The crosslinking agent may cause a crosslinking reaction by self-condensation. However, when the polymer of the invention includes a crosslink-forming substituent, the crosslinking agent may cause a crosslinking reaction with the crosslink-forming substituent.

<Acid or Acid Generator>

The neutralization layer-forming composition according to this invention may contain an acid and/or an acid generator as a catalyst for promoting a crosslinking reaction. Examples of the acid include acidic compounds such as p-toluenesulfonic acid, trifluoromethanesulfonic acid, pyridinium p-toluenesulfonic acid (=pyridinium-p-toluenesulfonate), salicylic acid, sulfosalicylic acid, citric acid, benzoic acid, hydroxybenzoic acid, and naphthalenecarboxylic acid. Examples of the acid generator include thermal acid generators such as 2,4,4,6-tetrabromocyclohexadienone, benzoin tosylate, 2-nitrobenzyl tosylate, and other organic sulfonic acid alkyl esters. The amount of these examples contained in the total solid content of the neutralization layer-forming composition of the invention is within the range of 0.0001 to 20% by mass, preferably 0.0005 to 10% by mass, and preferably 0.01 to 3% by mass.

Not only a thermal acid generator but also a photoacid generator may be employed as the acid generator.

Examples of the photoacid generator contained in the neutralization layer-forming composition of the invention include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoronormal butanesulfonate, diphenyliodonium perfluoronormal octanesulfonate, diphenyliodonium camphorsulfonate, bis(4-tert-butylphenyl) iodonium camphorsulfonate, and bis(4-tert-butylphenyl) iodonium trifluoromethanesulfonate, and sulfonium salt compounds such as triphenylsulfonium hexafluoroantimonate, triphenylsulfonium nonafluoronormal butanesulfonate, triphenylsulfonium camphorsulfonate, and triphenylsulfonium trifluoromethanesulfonate.

Examples of the sulfonimide compound include
N-(trifluoromethanesulfonyloxy) succinimide, N-(nonafluoronormalbutanesulfonyloxy) succinimide, N-(camphorsulfonyloxy) succinimide, and N-(trifluoromethanesulfonyloxy) naphthalimide.

Examples of the disulfonyl diazomethane compound include
bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

These photoacid generators may be used each alone or in combination of two or more thereof.

In a case where a photoacid generator is used, the proportion of the photoacid generator is within the range of 0.01 to 5 parts by mass, 0.1 to 3 parts by mass, or 0.5 to 1 parts by mass per 100 parts by mass of the solid content in the neutralization layer-forming composition of the invention.

With regard to the neutralization layer-forming composition containing the polymer having a polycyclic aromatic vinyl compound-derived unit structure and used for forming the neutralization layer, other details not described herein are referred to the description on an underlayer film-forming composition for a self-assembled film in WO 2014/097993 A.

Another example of the neutralization layer may be an underlayer film formed from an underlayer film-forming composition disclosed in WO 2018/135455 A, which is used for phase separation of a block copolymer-containing layer formed on a substrate and represented by the following copolymers:
a unit structure (A) derived from a tert-butyl group-containing styrene compound,
a unit structure (B) different from the unit structure (A) and derived from an aromatic compound-containing and hydroxy group-free vinyl compound,
a unit structure (C) derived from a (meth)acryloyl group-containing and hydroxy group-free compound, and
a unit structure (D) derived from a crosslink-forming group-containing compound; the ratio of each unit structure to the total copolymer being: (A) 25 to 90% by mole, (B) 0 to 65% by mole, (C) 0 to 65% by mole, and (D) 10 to 20% by mole; and the aromatic compound-containing unit structures in (A)+(B)+(C) accounting for 81 to 90% by mole.

The unit structure (A) derived from a tert-butyl group-containing styrene compound may be represented by Formula (1).

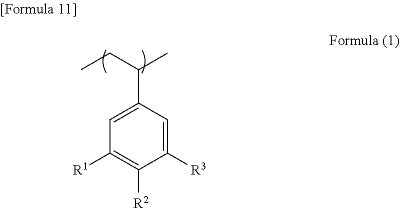

(In Formula (1), one or two of R¹ to R³ is a tert-butyl group.)

The unit structure (D) derived from a crosslink-forming group-containing compound may be represented by Formula (2-1), (2-2), (3-1), or (3-2).

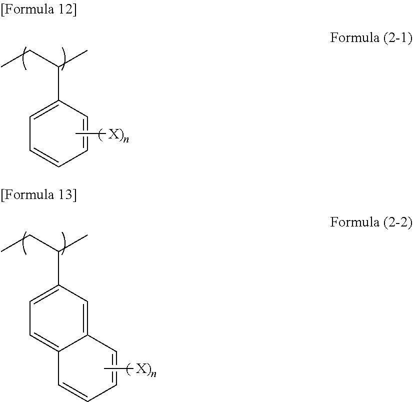

(In Formulae (2-1) and (2-2), n quantity of X independently are a hydroxy group, a halogen atom, an alkyl group, an alkoxy group, a cyano group, an amide group, an alkoxycarbonyl group, or a thioalkyl group, and n is an integer of 1 to 7.)

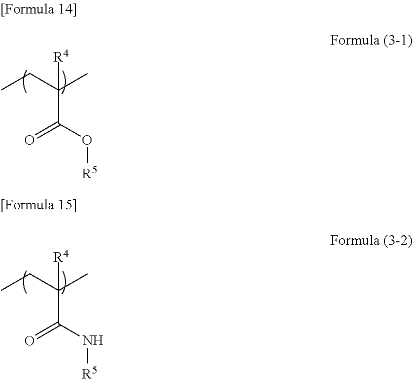

### (In Formulae (3-1) and (3-2),

R⁴ is a hydrogen atom or a methyl group,

R⁵ is a C₁-C₁₀ straight, branched, or cyclic alkyl group, or hydroxyphenyl group which has a hydroxy group and is optionally substituted with a halogen atom.)

The unit structure (B) different from the unit structure (A) and derived from an aromatic compound-containing and hydroxy group-free vinyl compound may be represented by Formula (4-1) or (4-2).

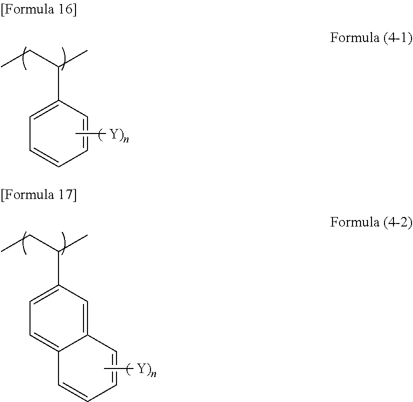

(In Formulae (4-1) and (4-2), n quantity of Y independently are a halogen atom, an alkyl group, an alkoxy group, a cyano group, an amide group, an alkoxycarbonyl group, or a thioalkyl group, and n is an integer of 0 to 7.)

The unit structure (C) derived from a (meth)acryloyl group-containing and hydroxy group-free compound may be represented by Formula (5-1) or (5-2).

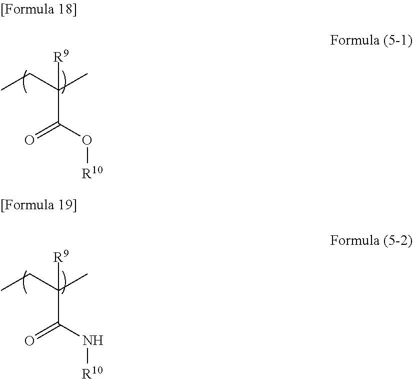

(In Formulae (5-1) and (5-2), R⁹ is a hydrogen atom or a methyl group, each R¹⁰ independently is a hydrogen atom, a C₁-C₅ alkoxy group, a C₁-C₁₀ straight, branched, or cyclic alkyl group optionally substituted with a halogen atom, a benzyl group, or an anthrylmethyl group.)

The unit structure (B) different from the unit structure (A) and derived from an aromatic compound-containing and hydroxy group-free vinyl compound may be a unit structure derived from vinylnaphthalene.

Other details of the underlayer film-forming composition of the invention not described herein are referred to the description in WO 2018/135455 A.

Another example of the neutralization layer may be a neutralization layer disclosed in JP 2012-062365 A, which is formed from a base material used for phase separation of a layer containing a block copolymer to which a plurality of types of polymers is bonded and formed on a substrate, the base material containing a resin component and having a constituting unit derived from an aromatic ring-containing monomer in an amount of 2% by mole to 80% by mole of the total resin component.

The resin component may contain a constituting unit derived from a non-aromatic ring-containing monomer.

The non-aromatic ring-containing monomer may be a vinyl compound or a (meth)acrylic acid compound containing at least one atom selected from the group consisting of N, O, Si, P, and S.

The aromatic ring-containing monomer may be selected from the group consisting of a C₆-C₁₈ aromatic compound having a vinyl group, a C₆-C₁₈ aromatic compound having a (meth)acryloyl group, and a phenol as a component of novolac resins. Moreover, the aromatic ring-containing monomer may have a polymerizable monomer, or the resin component may contain a polymerizable group.

The term “(meth)acrylic acid” represents one or both of an acrylic acid having a hydrogen atom bonded to α-carbon and a methacrylic acid having a methyl group bonded to α-carbon. The same applies to the terms “(meth)acrylic acid ester”, “(meth)acrylate” and “(meth)acryloyl.”

Examples of the C₆-C₁₈ aromatic compound having a vinyl group include monomers having a group containing such an aromatic ring as phenyl, biphenyl, fluorenyl, naphthyl, anthryl or phenanthryl group, of which a hydrogen atom is substituted with a vinyl group, and monomers having a heteroaryl group, in which a part of carbon atoms in the ring of the aforementioned vinyl-substituted aromatic groups is substituted with such a heteroatom as oxygen, sulfur or nitrogen atom. These compounds may have a substituent other than the vinyl group.

Examples of the substituent include a-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

Examples of the C₆-C₁₈ aromatic compound having a (meth)acryloyl group include monomers having a group containing such an aromatic ring as phenyl, biphenyl, fluorenyl, naphthyl, anthryl or phenanthryl group, of which a hydrogen atom is substituted with a (meth)acryloyl group, and monomers having a heteroaryl group, in which a part of carbon atoms in the ring of the aforementioned (meth)acryloyl-substituted aromatic groups is substituted with such a heteroatom as oxygen, sulfur or nitrogen atom. These compounds may have a substituent other than the (meth)acryloyl group.

Examples of the substituent include benzyl methacrylate, 1-(meth)acrylic acid-naphthalene, 4-methoxynaphthalene (meth)acrylate, 9-(meth)acrylic acid anthracene, and phenoxyethyl (meth)acrylate. Other details of the base material not mentioned herein are referred to the description in JP 2012-062365 A.

The polymer contained in the neutralization layer herein has a weight average molecular weight of 1,000 to 50,000, or 2,000 to 30,000, for example.

The neutralization layer-forming composition herein preferably contains the polymer used in the neutralization layer and a solvent. Specific preferred examples of the solvent are the same as those contained in the block copolymer layer-forming composition (preferably the PS-b-PMMA layer-forming composition).

In an embodiment of the invention, the neutralization layer may contain a polymer having a unit structure containing an aliphatic polycyclic structure of an aliphatic polycyclic compound in the main chain.

The polymer may have a unit structure containing an aliphatic polycyclic structure of an aliphatic polycyclic compound and an aromatic ring structure of an aromatic ring-containing compound in the main chain.

The polymer may have a unit structure containing an aliphatic polycyclic structure of an aliphatic polycyclic compound and a polymeric chain derived from a vinyl group of a vinyl group-containing compound in the main chain.

The polymer may have a unit structure represented by the following Formula (1a):

[Formula 20]

[symbol]

X−Y [symbol] Formula (1a)

(In Formula (1a), X is a single-bonded divalent group having a vinyl structure derived from a vinyl group-containing compound as a polymeric chain, or divalent group having an aromatic ring-containing structure derived from an aromatic ring-containing compound as a polymeric chain, and Y is a divalent group having an aliphatic polycyclic structure derived from an aliphatic polycyclic compound as a polymeric chain.)

The aliphatic polycyclic compound may be a diene compound having two to six rings.

The aliphatic polycyclic compound may be dicyclopentadiene or norbornadiene.

The vinyl group-containing compound may be alkene, acrylate, or methacrylate. The aromatic ring-containing compound may be a homocyclic compound or a heterocyclic compound.

The homocyclic compound may be optionally substituted benzene or optionally substituted naphthalene.

The heterocyclic compound may be optionally substituted carbazole or optionally substituted phenothiazine.

The polymer represented by Formula (1a) have a unit structure represented bythe following Formulae (3-1a) to (3-12a), for example.

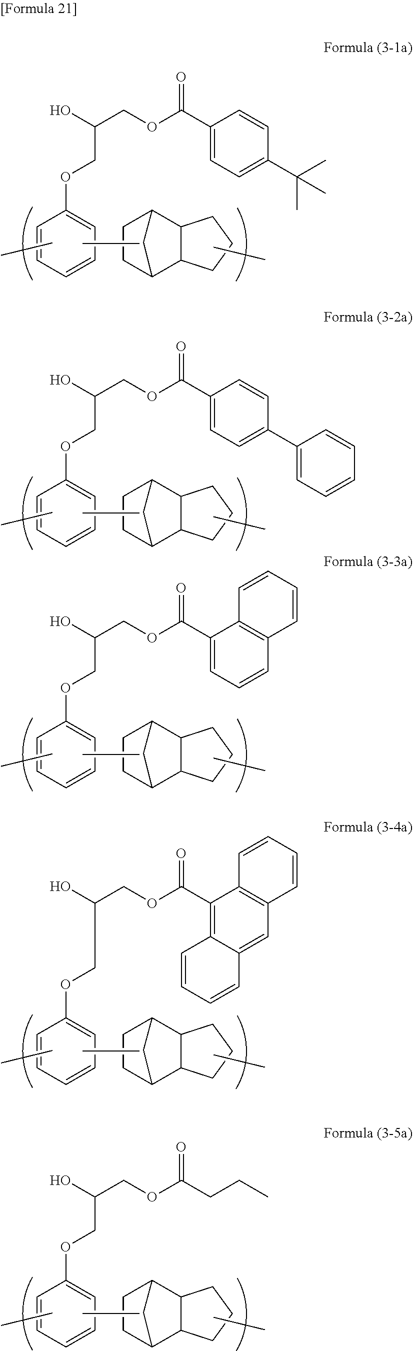

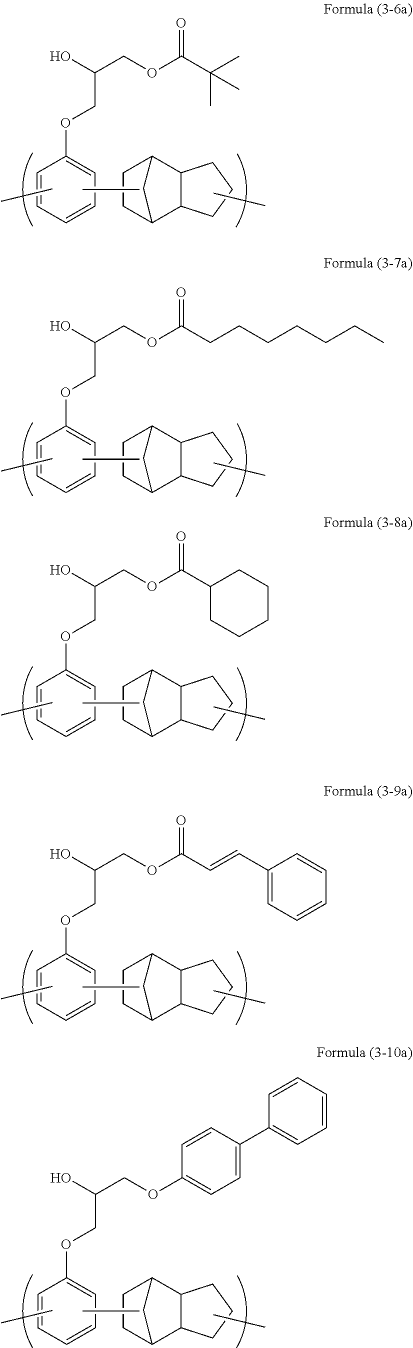

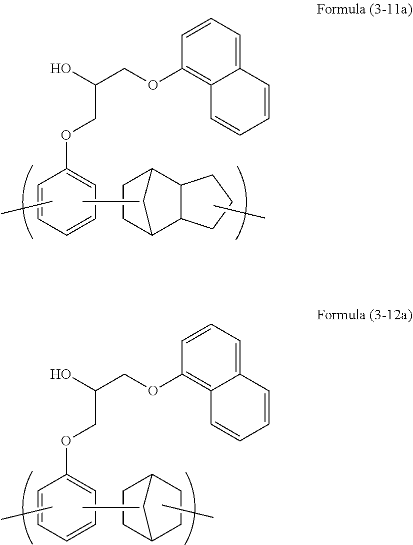

Details of the neutralization layer containing a polymer having a unit structure containing an aliphatic polycyclic structure of an aliphatic polycyclic compound in the main chain are referred to the description in WO 2015/041208 A.

The neutralization layer herein may contain polysiloxane.

The polysiloxane may be a hydrolytic condensate of phenyl group-containing silane.

The polysiloxane may be a hydrolytic condensate of silane, which contains a silane represented by Formula (1b) in a proportion of 10 to 100% by mole of the total silane:

[Formula 22]

R²Si(R¹)₃ Formula (1b)

(In Formula, R¹ is an alkoxy group, an acyloxy group, or a halogen atom. R² is an organic group having an optionally substituted benzene ring bonded to a silicon atom through a Si—C bond). Preferably, the proportion of the silane represented by Formula (1b) is within the range of 60 to 100% by mole.

The polysiloxane may be a hydrolytic condensate of silane, which contains a silane represented by Formula (1b), a silane represented by the following Formula (2b), and a silane represented by the following Formula (3b) in a ratio of 10 to 100:0 to 90:0 to 50 in terms of % by mole of the total silane.

[Formula 23]

R⁴Si(R³)₃ Formula (2b)

Si(R⁵)₄ Formula (3b)

(In Formula, R³ and R⁵ represent an alkoxy group, an acyloxy group, or a halogen atom, and R⁴ represents an organic group having an optionally substituted hydrocarbon bonded to a silicon atom through a Si—C bond.)

The polysiloxane may be a hydrolytic condensate of silane, which contains a silane represented by Formula (1b) and a silane represented by Formula (2b) in a ratio of 10 to 100:0 to 90 in terms of % by mole of the total silane.

The polysiloxane may be a hydrolytic condensate of silane, which contains a silane represented by Formula (1b) and a silane represented by Formula (3b) in a ratio of 10 to 100:0 to 90 in terms of % by mole of the total silane.

In Formula (1b), R² may be a phenyl group. In Formula (2b), R⁴ may be a methyl group or a vinyl group. In Formula (3b), R⁵ may be an ethyl group.

Details of the neutralization layer containing polysiloxane are referred to the description in WO 2013/146600 A.

A brush may be used as the neutralization layer to form a vertically phase-separated block copolymer layer, or preferably a vertically phase-separated PS-b-PMMA layer.

For example, an underlayer (neutralization layer) of a block copolymer may be formed by the method using polymer brushing disclosed in JP 2016-160431 A, wherein in the method, on a substrate is placed a composition containing a solvent, a block copolymer containing a first polymer and a second polymer, which are different from each other and form a separated-layer structure, and an additional polymer containing a bottlebrush polymer, which has a lower or higher surface energy than does the block copolymer.

A method using a brush disclosed in Science 7 Mar. 1997: Vol. 275, Issue 5305, pp. 1458-1460 is also applicable.

A preferred brush herein contains a polymer having a reactive substituent at a terminal. In other words, in an embodiment of this application, the neutralization layer contains a polymer having a reactive substituent at a terminal.

The reactive substituent represents a substituent capable of bonding to silicon, SiN, SiON, silicon hardmask, etc., and contributes to the ordering of a block copolymer as the so-called brush. Examples of the reactive substituent include hydroxy group, 1,2-ethanediol group, carboxy group, amino group, thiol group, phosphate group, and methine group.

A specific example of the polymer having a reactive substituent at a terminal is a polystyrene/poly(methyl methacrylate)) random copolymer having a hydroxy group at a terminal. The molar ratio of the polystyrene to the total random copolymer is preferably 60% by mole or more, 65% by mole or more, 70% by mole or more, 80% by mole or more, 81% by mole or more, 85% by mole or more, or 90% by mole or more. The polymer contained in the brush has a weight average molecular weight ranging from, for example, 5,000 to 50,000. The polydispersity (Mw/Mn) is preferably within the range of 1.10 to 2.00.

A known hardmask (also referred to as silicon-containing resist underlayer film) may be employed as the silicon hardmask, and examples thereof include those disclosed in WO 2019/181873 A, WO 2019/124514 A, WO 2019/082934 A, WO 2019/009413 A, WO 2018/181989 A, WO 2018/079599 A, WO 2017/145809 A, and WO 2017/145808 A, WO 2016/031563 A.

<Substrate>

The vertically phase-separated block copolymer layer, or preferably the vertically phase-separated PS-b-PMMA layer, is preferably formed on a substrate.

The substrate may be a semiconductor substrate, that is, a silicon wafer, a germanium wafer, or a compound semiconductor wafer such as gallium arsenide, indium phosphide, gallium nitride, indium nitride, and aluminum nitride.

When employing a semiconductor substrate having a surface provided with an inorganic film, the inorganic film is formed by, for example, atomic layer deposition (ALD), chemical vapor deposition (CVD), reactive sputtering, ion plating, vacuum deposition, or spin coating (spin on glass: SOG). Examples of the inorganic film include polysilicon film, silicon oxide film, silicon nitride film, boro-phospho silicate glass (BPSG) film, titanium nitride film, titanium nitride oxide film, tungsten film, gallium nitride film, and gallium arsenide film.

The neutralization layer-forming composition is applied to one of these semiconductor substrates by a spinner or a coater, for example. Thereafter, the composition is baked with a heating unit such as a hot plate, thereby forming a neutralization layer. With regard to conditions of the baking, the baking temperature is appropriately selected from a range of 100° C. to 400° C., and the baking time is appropriately selected from a range of 0.3 minutes to 60 minutes. Preferably, the baking is carried out at a temperature of 120° C. to 350° C. for 0.5 minutes to 30 minutes, and more preferably, at a temperature of 150° C. to 300° C. for 0.8 minutes to 10 minutes.

The neutralization layer to be formed has a thickness of, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), or 0.005 μm (5 nm) to 0.02 μm (20 nm).

The block copolymer layer is phase-separated by ultrasonic treatment, solvent treatment, thermal annealing, or other treatments that cause reordering of the block copolymer material in the presence of an upper layer film. In many applications, it is desirable to achieve phase separation of a block copolymer layer simply by heating or what is called thermal annealing. The thermal annealing is performed under normal pressure, reduced pressure, or pressurized conditions in the air or in an inert gas.

<Method for Producing Vertically Phase-Separated Block Copolymer Layer>

A method for producing a vertically phase-separated block copolymer layer, or preferably a vertically phase-separated PS-b-PMMA layer, herein involves forming a block copolymer layer, or preferably a PS-b-PMMA layer, on a substrate, and then, heating the substrate under a pressure below atmospheric pressure. Details and conditions according to the method are the same as those described for the vertically phase-separated block copolymer layer, or preferably the PS-b-PMMA layer.

The phase separation of the block copolymer layer, or preferably the PS-b-PMMA layer, forms block copolymer domains substantially vertically oriented relative to the substrate or the surface of the neutralization layer. The domains have a shape of, for example, lamella, sphere, or cylinder (column). The domains have an interval of, for example, 50 nm or less, 40 nm or less, 30 nm or less, 20 nm or less, or nm or less. The method of the invention enables formation of a vertically phase-separated block copolymer layer, or preferably a vertically phase-separated PS-b-PMMA layer, having a desired size, shape, order, and periodicity.

<Method for Manufacturing Semiconductor Device>

In the method, the vertically phase-separated block copolymer layer, or preferably the vertically phase-separated PS-b-PMMA layer, is subjected to etching. Typically, a part of the phase-separated block copolymer layer, or preferably a part of the phase-separated PS-b-PMMA layer, is removed before the etching. The etching is carried out by a known technique. This method is applicable for manufacturing of a semiconductor substrate.

That is, the method for manufacturing a semiconductor device according to the invention involves (1) forming a neutralization layer on a substrate using a neutralization layer-forming composition according to the invention, (2) forming a block copolymer layer, or preferably a PS-b-PMMA layer, on the neutralization layer, (3) inducing phase separation of the block copolymer layer, or preferably the PS-b-PMMA layer, formed on the neutralization layer, (4) etching the phase-separated block copolymer layer, or preferably the phase-separated PS-b-PMMA layer, and (5) etching the substrate.

The etching may use a gas such as tetrafluoromethane (CF₄), perfluorocyclobutane (C₄F₈), perfluoropropane (C₃F₈), trifluoromethane, monoxide, argon, oxygen, nitrogen, sulfur hexafluoride, difluoromethane, nitrogen trifluoride, chlorine trifluoride, chlorine, trichloroborane, and dichloroborane.

Utilizing patterns of the vertically phase-separated block copolymer layer, or preferably the vertically phase-separated PS-b-PMMA layer, according to the invention provides a substrate to be etched with a desired shape and enables manufacturing of a preferable semiconductor device.

### EXAMPLES

Hereinafter, the invention will be described in detail with reference to Examples and Comparative Example, but the invention is not limited to the following examples.

### Example 1

### Preparation of Block Copolymer 1

0.5 g of a polystyrene/poly(methyl methacrylate) copolymer (available from Polymer Source Inc., PS (Mw: 22,000, Mn: 21,000)-b-PMMA (Mw: 22,900, Mn: 21,000), polydispersity=1.07) as a block copolymer was dissolved in 24.5 g of propylene glycol monomethyl ether acetate to prepare a 2% by mass solution. The solution was filtrated through a polyethylene microfilter having a pore size of 0.02 μm, thereby preparing a self-assembled film-forming composition 1 containing the block copolymer 1.

The weight average molecular weights (Mw) of the polymers shown in the following Synthesis Examples are determined by gel permeation chromatography (GPC). The chromatography was performed under the following conditions with a GPC apparatus available from Tosoh Corporation.
Measuring apparatus: HLC-8020GPC (trade name) (available from Tosoh Corporation)
GPC column: two TSKgel G2000HXL (trade name) columns, one G3000HXL (trade name) column, and one G4000HXL (trade name) column (all available from Tosoh Corporation)
Column temperature: 40° C.
Solvent: Tetrahydrofuran (THF)
Flow rate: 1.0 ml/min
Reference sample: Polystyrene (available from Tosoh Corporation)

### Preparation of Block Copolymer 2

A solution of a block copolymer 2 was prepared in the same manner as in the preparation of block copolymer 1 except that the polystyrene/poly(methyl methacrylate) copolymer (available from Polymer Source Inc., PS (Mw: 22,000, Mn: 21,000)-b-PMMA (Mw: 22,900, Mn: 21,000), polydispersity=1.07) was replaced by a polystyrene/poly(methyl methacrylate) copolymer (available form Polymer Source Inc., PS (Mw: 35,500, Mn: 33,000)-b-PMMA (Mw: 36,400, Mn: 33,000), polydispersity=1.09).

### [Synthesis Example 1] Synthesis of Polymer 1

In 22.50 g of propylene glycol monomethyl ether acetate, 6.23 g of 2-vinylnaphthalene (molar ratio to the total polymer 1 was 85%), 0.93 g of hydroxyethyl methacrylate (molar ratio to the total polymer 1 was 15%), and 0.36 g of 2,2′-azobisisobutyronitrile were dissolved. The resulting solution was heated and stirred at 85° C. for about 24 hours. The reaction solution was added to methanol by drops. The precipitate was collected by suction filtration and dried at 60° C. at reduced pressure, thereby collecting a polymer 1. The polystyrene-equivalent weight average molecular weight Mw determined by GPC was 6,000.

### [Synthesis Example 2] Synthesis of Polymer 2

In 22.50 g of propylene glycol monomethyl ether acetate, 4.77 g of 2-vinylnaphthalene (molar ratio to the total polymer 2 was 60%), 1.34 g of hydroxyethyl methacrylate (molar ratio to the total polymer 2 was 20%), 1.03 g of methyl methacrylate (molar ratio to the total polymer 2 was 20%), and 0.36 g of 2,2′-azobisisobutyronitrile were dissolved. The resulting solution was heated and stirred at 85° C. for about 24 hours. The reaction solution was added to methanol by drops. The precipitate was collected by suction filtration and dried at 60° C. at reduced pressure, thereby collecting a polymer 2. The polystyrene-equivalent weight average molecular weight Mw determined by GPC was 6,000.

### [Synthesis Example 3] Synthesis of Polymer 3

In 22.50 g of propylene glycol monomethyl ether acetate, 2.57 g of 2-vinylnaphthalene (molar ratio to the total polymer 3 was 50%), 2.06 g of benzyl methacrylate (molar ratio to the total polymer 3 was 35%), 0.72 g of hydroxyethyl methacrylate (molar ratio to the total polymer 3 was 15%), and 0.33 g of 2,2′-azobisisobutyronitrile were dissolved. The resulting solution was heated and stirred at 85° C. for about 24 hours. The reaction solution was added to methanol by drops. The precipitate was collected by suction filtration and dried at 60° C. at reduced pressure, thereby collecting a polymer 3. The polystyrene-equivalent weight average molecular weight Mw determined by GPC was 5,900.

### [Synthesis Example 4] Synthesis of Polymer 4

In 22.50 g of propylene glycol monomethyl ether acetate, 6.13 g of 2-vinylnaphthalene (molar ratio to the total polymer 4 was 85%), 1.01 g of hydroxypropyl methacrylate (molar ratio to the total polymer 4 was 15%), and 0.36 g of 2,2′-azobisisobutyronitrile were dissolved. The resulting solution was heated and stirred at 85° C. for about 24 hours. The reaction solution was added to methanol by drops. The precipitate was collected by suction filtration and dried at 60° C. at reduced pressure, thereby collecting a polymer 4. The polystyrene-equivalent weight average molecular weight Mw determined by GPC was 6,200.

### [Synthesis Example 5] Synthesis of Polymer 5

In 30.89 g of propylene glycol monomethyl ether acetate, 11.00 g of vinylcarbazole (molar ratio to the total polymer 5 was 80%), 1.85 g of hydroxyethyl methacrylate (molar ratio to the total polymer 5 was 20%), and 0.39 g of 2,2′-azobisisobutyronitrile were dissolved. The resulting solution was heated and stirred at 85° C. for about 19 hours. The polystyrene-equivalent weight average molecular weight Mw of the obtained polymer 5 determined by GPC was 6,950.

### [Synthesis Example 6] Synthesis of Polymer 6

34.98 g of propylene glycol monomethyl ether was added to 5.00 g of dicyclopentadiene-type epoxy resin (trade name: EPICLON HP-7200H, available from DIC Corporation), 3.58 g of 4-phenylbenzoic acid, and 0.17 g of ethyltriphenylphosphonium bromide. The resulting mixture was heated to reflux for 16 hours under a nitrogen atmosphere. The polystyrene-equivalent weight average molecular weight Mw of the obtained polymer 6 determined by GPC was 1,800.

### [Synthesis Example 7] Synthesis of Polymer 7

36.89 g of propylene glycol monomethyl ether was added to 5.50 g of dicyclopentadiene-type epoxy resin (trade name: EPICLON HP-7200H, available from DIC Corporation), 3.54 g of 4-tert-butylbenzoic acid, and 0.18 g of ethyltriphenylphosphonium bromide. The resulting mixture was heated to reflux for hours under a nitrogen atmosphere. The polystyrene-equivalent weight average molecular weight Mw of the obtained polymer 7 determined by GPC was 2,000.

### [Synthesis Example 8] Synthesis of Polymer 8

Phenyltrimethoxysilane in an amount of 13.88 g (70% by mole of the total silane), tetraethoxysilane in an amount of 5.35 g (30% by mole of the total silane), and acetone in an amount of 28.84 g were put in a 100 ml flask. While the mixed solution was stirred with a magnetic stirrer, 5.41 g of 0.01 mol/l hydrochloric acid was added to the mixed solution by drops. After the addition, the flask was moved to an oil bath adjusted to a temperature of 85° C. and heated to reflux for four hours to carry out a reaction. Thereafter, the reaction solution was cooled to room temperature, and 75 g of propylene glycol monomethyl ether acetate was added to the reaction solution, followed by distillation of reaction by-products such as methanol, ethanol, water, and hydrochloric acid under reduced pressure, thereby obtaining a concentrated polymer solution. Propylene glycol monoethyl ether was added to the concentrated polymer solution so as to adjust the solvent ratio of propylene glycol monomethyl ether acetate/propylene glycol monoethyl ether to 20/80. The polystyrene-equivalent weight average molecular weight Mw of the obtained polymer 8 determined by GPC was 1,200.

### Preparation of Underlayer Film-Forming Composition 1

In 0.39 g of the polymer obtained in Synthesis Example 1 were mixed 0.10 g of tetramethoxymethyl glycoluril and 0.05 g of pyridinium-p-toluenesulfonate. To this mixture, 69.65 g of propylene glycol monomethyl ether acetate and 29.37 g of propylene glycol monomethyl ether were added and dissolved. After the dissolution, the solution was filtered through a polyethylene microfilter having a pore size of 0.02 μm, thereby preparing a solution of underlayer film-forming composition 1 for a self-assembled film.

### Preparation of Underlayer Film-Forming Compositions 2 to 5

Underlayer film-forming compositions 2 to 5 were prepared in the same manner as in the preparation of the underlayer film-forming composition 1 except that the polymer obtained in Synthesis Example 1 was replaced by each of the polymers obtained in Synthesis Examples 2 to 5.

### Preparation of Underlayer Film-Forming Composition 6

In 0.26 g of the polymer obtained in Synthesis Example 6 were mixed 0.07 g of tetramethoxymethyl glycoluril and 0.007 g of pyridinium-p-toluenesulfonate. To this mixture, 8.90 g of propylene glycol monomethyl ether acetate and 20.76 g of propylene glycol monomethyl ether were added and dissolved. After the dissolution, the solution was filtered through a polyethylene microfilter having a pore size of 0.02 μm, thereby preparing a solution of underlayer film-forming composition 6 for a self-assembled film.

### Preparation of Underlayer Film-Forming Composition 7

An underlayer film-forming composition 7 was prepared in the same manner as in the preparation of the underlayer film-forming composition 6 except that the polymer obtained in Synthesis Example 6 was replaced by the polymer obtained in Synthesis Example 7.

### Preparation of Underlayer Film-Forming Composition 8

In 1.33 g of the polymer obtained in Synthesis Example 8 were mixed 0.006 g of maleic acid and 0.0012 g of benzyltriethylammonium chloride. To this mixture, 0.68 g of propylene glycol monomethyl ether acetate, 0.79 g of propylene glycol monomethyl ether, 9.10 g of 1-ethoxy-2-propanol, and 1.30 g of ultrapure water were added and dissolved. After the dissolution, the solution was filtered through a fluororesin microfilter having a pore size of 0.1 μm, thereby preparing a solution of underlayer film-forming composition 8 for a self-assembled film.

### Preparation of Underlayer Film-Forming Composition 9 Using Brush

A polystyrene/poly(methyl methacrylate) copolymer (available from Polymer Source Inc., molar ratio of polystyrene was 72%, molar ratio of poly(methacrylate) was 28%, Mw=8,120, polydispersity=1.16) in an amount of 0.3 g having a hydroxy group at a terminal was dissolved in 29.7 g of propylene glycol monomethyl ether acetate to prepare a 1% by mass solution. The solution was filtrated through a polyethylene microfilter having a pore size of 0.02 μm, thereby preparing an underlayer film-forming composition 9 using a brush.

### Example 2

### Evaluation of Self-Assembly of Block Copolymer

The obtained underlayer film-forming composition 1 for a self-assembled film was applied to a silicon wafer and heated on a hot plate at 240° C. for one minute, thereby obtaining an underlayer film (A layer) having a thickness of 5 to 10 nm. The self-assembled film-forming composition containing the block copolymer 1 was applied onto the A layer with a spin coater and heated on the hot plate at 100° C. for one minute, thereby forming a self-assembled film (B layer) having a thickness of 40 nm. The self-assembled film-applied wafer was heated at 290° C. for 15 minutes under a pressure of 1,000 mTorr in an O₂/N₂ mixed gas atmosphere (the mixing ratio O₂:N₂=2:8 (flow ratio)) using an etching device (Lam 2300 MWS, available from Lam Research Corporation) to direct a microphase-separated structure of the self-assembled film.

### Examination of Microphase-Separated Structure

The silicon wafer having the directed microphase-separated structure was etched for three seconds with an etching apparatus (Lam 2300 Versys Kiyo 45, available from Lam Research Corporation), using an O₂/N₂ gas as etching gas to preferentially etch poly(methyl methacrylate) areas. Subsequently, the shape of the wafer was observed with an electron microscope (5-4800, available from Hitachi High-Tech Corporation).

### Examples 3 to 9

Observation of microphase-separated structure was conducted in the same manner as in Example 2 except that the underlayer film-forming composition 1 was replaced by each of the underlayer film-forming compositions 2 to 8.

### Examples 10 to 11

Observation of microphase-separated structure was conducted in the same manner as in Example 2 except that the heating under an O₂/N₂ mixed gas atmosphere was replaced by each of the heating under an N₂ gas atmosphere and O₂ gas atmosphere, respectively.

### Example 12

Observation of microphase-separated structure was conducted in the same manner as in Example 2 except that the heating at 290° C. for 15 minutes under a pressure below atmospheric pressure in the O₂/N₂ mixed gas atmosphere (the mixing ratio O₂:N₂=2:8 (flow ratio)) using the etching apparatus (Lam 2300 MWS, available from Lam Research Corporation) was replaced by the heating at 290° C. for 15 minutes under a pressure of 1,000 mTorr in a nitrogen atmosphere using vacuum annealing equipment (VJ-300-S, available from Ayumi Industry Co., Ltd.).

### Examples 13 to 19

Observation of microphase-separated structure was conducted in the same manner as in Example 12 except that the underlayer film-forming composition 1 was replaced by each of the underlayer film-forming compositions 2 to 8.

### Example 20 to 23

Observation of microphase-separated structure was conducted in the same manner as in Example 12 except that the heating at 290° C. was replaced by the heating at each of 240° C., 260° C., 270° C., and or 300° C., respectively.

### Example 24

Observation of microphase-separated structure was conducted in the same manner as in Example 12 except that the heating at 290° C. for 15 minutes was replaced by the heating at 320° C. for 5 minutes.

### Example 25 to 27

Observation of microphase-separated structure was conducted in the same manner as in Example 12 except that the heating under a pressure of 1,000 mTorr was replaced by the heating under a pressure of each of 500 mTorr, 5,000 mTorr, and 10,000 mTorr, respectively.

### Example 28

Observation of microphase-separated structure was conducted in the same manner as in Example 12 except that the solution of the block copolymer 1 was replaced by the solution of the block copolymer 2.

### Example 29

Observation of microphase-separated structure was conducted in the same manner as in Example 12 except for the following conditions. Instead of applying the underlayer film-forming composition 1 to the silicon wafer and heating at 240° C. for one minute on the hot plate, the underlayer film-forming composition 9 was applied to a silicon wafer and heated at 200° C. for two minutes, and then, the silicon wafer was immersed in propylene glycol monomethyl ether acetate to remove the polymers not attached to the silicon wafer, thereby forming an underlayer film.

### Comparative Example 1

Observation of microphase-separated structure was conducted in the same manner as in Example 2 except that the heating at 290° C. for 15 minutes under a pressure below atmospheric pressure in the O₂/N₂ mixed gas atmosphere using the etching apparatus (Lam 2300 MWS, available from Lam Research Corporation) was replaced by the heating at 290° C. for 15 minutes on a hot plate under atmospheric pressure (760,000 mTorr) in the air.

### Determination of Orientation of Block Copolymer

The orientation of each block copolymer prepared in Examples 2 to 29 and Comparative Example 1 was examined. Table 1 shows the results, and FIG. 3 shows examples of vertical order (vertically ordered lamellar structure) and disorder examined by an electron microscope (magnification: 200 K). Note that the term “vertical order” in Table 1 means “vertically ordered lamellar structure.”

TABLE 1

| | Block | | | | | | |
|---|---|---|---|---|---|---|---|
| | copolymer | Underlayer | | | | | |
| | forming | film-forming | | | | | Pattern |
| | composition | composition | Pressure | Temperature | Time | Atmosphere | ordering |
| Example 2 | Block | Polymer 1 | 1000 mTorr | 290° C. | 15 min | O₂/N₂ | Vertical |
| | copolymer 1 | | | | | | order |
| Example 3 | Block | Polymer 2 | 1000 mTorr | 290° C. | 15 min | O₂/N₂ | Vertical |
| | copolymer 1 | | | | | | order |
| Example 4 | Block | Polymer 3 | 1000 mTorr | 290° C. | 15 min | O₂/N₂ | Vertical |
| | copolymer 1 | | | | | | order |
| Example 5 | Block | Polymer 4 | 1000 mTorr | 290° C. | 15 min | O₂/N₂ | Vertical |
| | copolymer 1 | | | | | | order |
| Example 6 | Block | Polymer 5 | 1000 mTorr | 290° C. | 15 min | O₂/N₂ | Vertical |
| | copolymer 1 | | | | | | order |
| Example 7 | Block | Polymer 6 | 1000 mTorr | 290° C. | 15 min | O₂/N₂ | Vertical |
| | copolymer 1 | | | | | | order |
| Example 8 | Block | Polymer 7 | 1000 mTorr | 290° C. | 15 min | O₂/N₂ | Vertical |
| | copolymer 1 | | | | | | order |
| Example 9 | Block | Polymer 8 | 1000 mTorr | 290° C. | 15 min | O₂/N₂ | Vertical |
| | copolymer 1 | | | | | | order |
| Example 10 | Block | Polymer 1 | 1000 mTorr | 290° C. | 15 min | N₂ | Vertical |
| | copolymer 1 | | | | | | order |
| Example 11 | Block | Polymer 1 | 1000 mTorr | 290° C. | 15 min | O₂ | Vertical |
| | copolymer 1 | | | | | | order |
| Example 12 | Block | Polymer 1 | 1000 mTorr | 290° C. | 15 min | N₂ | Vertical |
| | copolymer 1 | | | | | | order |
| Example 13 | Block | Polymer 2 | 1000 mTorr | 290° C. | 15 min | N₂ | Vertical |
| | copolymer 1 | | | | | | order |
| Example 14 | Block | Polymer 3 | 1000 mTorr | 290° C. | 15 min | N₂ | Vertical |
| | copolymer 1 | | | | | | order |
| Example 15 | Block | Polymer 4 | 1000 mTorr | 290° C. | 15 min | N₂ | Vertical |
| | copolymer 1 | | | | | | order |
| Example 16 | Block | Polymer 5 | 1000 mTorr | 290° C. | 15 min | N₂ | Vertical |
| | copolymer 1 | | | | | | order |
| Example 17 | Block | Polymer 6 | 1000 mTorr | 290° C. | 15 min | N₂ | Vertical |
| | copolymer 1 | | | | | | order |
| Example 18 | Block | Polymer 7 | 1000 mTorr | 290° C. | 15 min | N₂ | Vertical |
| | copolymer 1 | | | | | | order |
| Example 19 | Block | Polymer 8 | 1000 mTorr | 290° C. | 15 min | N₂ | Vertical |
| | copolymer 1 | | | | | | order |
| Example 20 | Block | Polymer 1 | 1000 mTorr | 240° C. | 15 min | N₂ | Vertical |
| | copolymer 1 | | | | | | order |
| Example 21 | Block | Polymer 1 | 1000 mTorr | 260° C. | 15 min | N₂ | Vertical |
| | copolymer 1 | | | | | | order |
| Example 22 | Block | Polymer 1 | 1000 mTorr | 270° C. | 15 min | N₂ | Vertical |
| | copolymer 1 | | | | | | order |
| Example 23 | Block | Polymer 1 | 1000 mTorr | 300° C. | 15 min | N₂ | Vertical |
| | copolymer 1 | | | | | | order |
| Example 24 | Block | Polymer 1 | 1000 mTorr | 320° C. | 5 min | N₂ | Vertical |
| | copolymer 1 | | | | | | order |
| Example 25 | Block | Polymer 1 | 500 mTorr | 290° C. | 15 min | N₂ | Vertical |
| | copolymer 1 | | | | | | order |
| Example 26 | Block | Polymer 1 | 5000 mTorr | 290° C. | 15 min | N₂ | Vertical |
| | copolymer 1 | | | | | | order |
| Example 27 | Block | Polymer 1 | 10000 mTorr | 290° C. | 15 min | N₂ | Vertical |
| | copolymer 1 | | | | | | order |
| Example 28 | Block | Polymer 1 | 1000 mTorr | 290° C. | 15 min | N₂ | Vertical |
| | copolymer 2 | | | | | | order |
| Example 29 | Block | Brush | 1000 mTorr | 290° C. | 15 min | N₂ | Vertical |
| | copolymer 1 | polymer | | | | | order |
| Comparative | Block | Polymer 1 | Atmospheric | 290° C. | 15 min | Air | Disorder |
| example 1 | copolymer 1 | | pressure | | | | |

As shown in Table 1, the method of the invention for causing microphase separation by heating under a pressure below atmospheric pressure enables directed vertical order of a block copolymer, particularly a PS-b-PMMA block copolymer, at temperatures at which the directed self-assembly occurs, or preferably at high temperatures (290° C. or higher).

### INDUSTRIAL APPLICABILITY

According to the invention, it is possible to vertically direct a microphase-separated structure of a block copolymer-containing layer throughout a coating film on a substrate without causing disorder of the microphase separation of the block copolymer, and this is significantly useful in industry.

The disclosure of JP 2020-138906 (filing date: Aug. 19, 2020) is incorporated herein by reference in its entirety.

All documents, patent applications, and technical standards mentioned in this specification are incorporated herein by reference to the same extent as if each individual document, patent application, and technical standard is specifically and individually indicated to be incorporated by reference.

1. A layer comprising a block copolymer having a vertically phase-separated structure, the layer being formed by heating at a temperature at which a directed self-assembly may occur under a pressure below atmospheric pressure.

2. The layer comprising a block copolymer having a vertically phase-separated structure according to claim 1, wherein the block copolymer is PS-b-PMMA.

3. The layer comprising a block copolymer having a vertically phase-separated structure according to claim 1, wherein the vertically phase-separated structure includes a lamellar portion.

4. The layer comprising a block copolymer having a vertically phase-separated structure according to claim 1, wherein the heating is carried out at a temperature of 290° C. or higher.

5. The layer comprising a block copolymer having a vertically phase-separated structure according to claim 1, which further comprises under a layer of the block copolymer a neutralization layer that neutralizes a surface energy of the block copolymer.

6. The layer comprising a block copolymer having a vertically phase-separated structure according to claim 5, wherein the neutralization layer comprises a polymer having an aromatic compound-derived unit structure.

7. The layer comprising a block copolymer having a vertically phase-separated structure according to claim 6, wherein the aromatic compound-derived unit structure accounts for 50% by mole or more of the polymer.

8. The layer comprising a block copolymer having a vertically phase-separated structure according to claim 5, wherein the neutralization layer comprises a polymer having in its main chain a unit structure including an aliphatic polycyclic structure of an aliphatic polycyclic compound.

9. The layer comprising a block copolymer having a vertically phase-separated structure according to claim 5, wherein the neutralization layer comprises a polysiloxane.

10. The layer comprising a block copolymer having a vertically phase-separated structure according to claim 5, wherein the neutralization layer comprises a polymer having a reactive substituent at a terminal.

11. The layer comprising a block copolymer having a vertically phase-separated structure according to claim 1, which is formed on a substrate.

12. A method for producing a layer comprising a block copolymer having a vertically phase-separated structure, the method comprising:
forming a layer comprising a block copolymer on a substrate; and
heating the substrate under a pressure below atmospheric pressure.

13. A method for manufacturing a semiconductor device, the method comprising:
forming a layer comprising a block copolymer on a substrate;
heating the substrate under a pressure below atmospheric pressure;
etching the layer containing the block copolymer having a vertically phase-separated structure; and
etching the substrate.
